(19) United States
(12) Patent Application Publication
(10) Pub. No.: US 2024/0222094 A1
(43) Pub. Date: Jul. 4, 2024

(54) Workpiece Processing Apparatus with Contact Temperature Sensor

(71) Applicants: Beijing E-Town Semiconductor Technology Co., Ltd., Beijing (CN); Mattson Technology, Inc., Fremont, CA (US)

(72) Inventors: Zhaotong Yang, San Jose, CA (US); Calvin Wong, Dublin, CA (US); Hari Ambal, San Jose, CA (US); Avinash Shervegar, San Jose, CA (US)

(21) Appl. No.: 18/390,936

(22) Filed: Dec. 20, 2023

Related U.S. Application Data
(60) Provisional application No. 63/435,711, filed on Dec. 28, 2022.

(51) Int. Cl. H01J 37/32; G01K 11/3206

(52) U.S. Cl. CPC H01J 37/32724; G01K 11/3206; H01J 37/32467; H01J 37/32513; H01J 37/32522; H01J 2237/24585

(57) ABSTRACT

A semiconductor fabrication apparatus for processing one or more workpieces is provided. The apparatus includes one or more components exposed to radio frequency energy or heat and one or more optical contact temperature sensors disposed on the one or more components. Methods for measuring temperature of a component of a semiconductor fabrication apparatus are also provided.

### FIELD

The present disclosure relates generally to apparatuses, systems, and methods for processing a substrate using a plasma source.

### BACKGROUND

Plasma processing is widely used in the semiconductor industry for deposition, etching, resist removal, and related processing of semiconductor wafers and other substrates. Plasma sources (e.g., microwave, ECR, inductive, etc.) are often used for plasma processing to produce high density plasma and reactive species for processing substrates. Plasma strip tools can be used for strip processes, such as photoresist removal. Plasma strip tools can include a plasma chamber where plasma is generated and a separate processing chamber where the substrate is processed. The processing chamber can be “downstream” of the plasma chamber such that there is no direct exposure of the substrate to the plasma. A separation grid can be used to separate the processing chamber from the plasma chamber. The separation grid can be transparent to neutral species but not transparent to charged particles from the plasma. The separation grid can include a sheet of material with holes.

### SUMMARY

Aspects and advantages of embodiments of the present disclosure will be set forth in part in the following description, or may be learned from the description, or may be learned through practice of the embodiments.

One example aspect of the present disclosure is directed to a semiconductor fabrication apparatus for processing one or more workpieces. The apparatus includes one or more components exposed to radio frequency (RF) energy or heat and one or more optical contact temperature sensors. The one or more optical contact temperature sensors are disposed on the one or more components.

Another example aspect of the present disclosure is directed to an apparatus for processing a workpiece, the apparatus includes a plasma chamber having a sidewall, an inductively coupled plasma source configured to generate a plasma in the plasma chamber, a processing chamber separated from the plasma chamber via a separation grid; a pedestal disposed in the processing chamber, the pedestal configured to support a workpiece during processing; an optical contact temperature sensor. The optical contact temperature sensor is disposed on at least one of (i) the sidewall of the plasma chamber (ii) the separation grid or (iii) the pedestal.

Another example aspect of the present disclosure is directed to a method for measuring the temperature of a component of a semiconductor fabrication apparatus. The method includes utilizing an optical contact temperature sensor to generate data regarding temperature of a component part. The optical contact temperature sensor is disposed on the component part. The method also includes determining the temperature of the component part based, at least in part, on the data obtained from the optical contact temperature sensor.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts an example optical contact temperature sensor according to example aspects of the present disclosure;

FIG. 2 depicts an example plasma processing apparatus according to example embodiments of the present disclosure;

FIG. 3 depicts an example plasma processing apparatus according to example embodiments of the present disclosure;

FIG. 4 depicts an example plasma processing apparatus according to example embodiments of the present disclosure;

FIG. 5 depicts an example sidewall of a plasma chamber of a plasma processing apparatus according to example embodiments of the present disclosure;

FIG. 6 depicts an example sidewall of a plasma chamber according to example embodiments of the present disclosure;

FIG. 7 depicts an example grid plate of a separation grid of a plasma processing apparatus according to example embodiments of the present disclosure;

FIG. 8 depicts an example grid plate of a separation grid of a plasma processing apparatus according to example embodiments of the present disclosure;

FIG. 9 depicts an example ceiling of a plasma processing apparatus according to example embodiments of the present disclosure;

FIG. 10 depicts an example pedestal of a plasma processing apparatus according to example embodiments of the present disclosure;

FIG. 11 depicts an example plasma processing apparatus according to example embodiments of the present disclosure;

FIG. 12 depicts an example dielectric window of the plasma processing apparatus of FIG. 11 according to example embodiments of the present disclosure; and

FIG. 13 depicts a flow diagram of an example temperature measurement process according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Semiconductor fabrication equipment can be subjected to harsh conditions. For example, plasma processing of workpieces can involve generating plasma from process gases in a plasma chamber. Generators, such as inductively coupled power sources or capacitively coupled power sources can be used to generate the plasma. Components of the plasma chamber, for example the sidewalls of the plasma chamber, can be exposed to radio frequency (RF) energy or heat during operation of the apparatus. Additionally, other chambers such as processing chambers can be exposed to thermomechanical stresses from RF energy or heat as well. Frequent exposures or extreme exposures can severely negate the operable lifetime of the component part. Further, it can be difficult to accurately measure thermomechanical stresses (e.g., temperature) of component parts. Further, different portions of the component part can be subjected to different thermomechanical stresses, such as heat or RF energy. This can cause portions of the part to degrade or become damaged at rates faster than other portions of the component part. It can be difficult to accurately obtain real time temperature measurements of the component part along different locations of the component part.

Accordingly, example aspects of the present disclosure are directed to semiconductor fabrication apparatus for processing one or more workpieces. The apparatus includes one or more components exposed to RF energy or heat. The apparatus also includes one or more optical contact temperature sensors disposed on the one or more components. The optical contact temperature sensor can be configured to accurately measure the temperature of the component part. Furthermore, the optical contact temperature sensor can be configured such that it can measure the temperature of the component part at different locations in real time.

Aspects of the present disclosure provide a number of technical effects and benefits. For instance, the apparatus allows for the real time measurement of the temperature of component parts in a semiconductor processing apparatus. Such temperature information can more accurately inform component part life cycle. Thus, component parts only need to be replaced upon reaching a certain exposure threshold level to heat or RF energy, which can more easily and accurately be determined as provided herein. Accordingly, only component parts that have reached certain threshold exposure limits are replace or recondition in a timelier manner saving time and costs. Further, run downtime for semiconductor apparatuses can be reduced, since component parts are only being replaced or reconditioned upon reaching certain thermomechanical stress levels. Additionally, utilization of the sensor as disclosed herein do not require additional filtering or processing steps in order to effectively determine the temperature from data provided by such sensors. As such, processing is simplified and more efficient.

Variations and modifications can be made to these example embodiments of the present disclosure. As used in the specification, the singular forms “a,” “and,” and “the” include plural referents unless the context clearly dictates otherwise. The use of “first,” “second,” “third,” etc., are used as identifiers and are not necessarily indicative of any ordering, implied or otherwise. Example aspects may be discussed with reference to a “substrate,” “workpiece,” or “workpiece” for purposes of illustration and discussion. Those of ordinary skill in the art, using the disclosures provided herein, will understand that example aspects of the present disclosure can be used with any suitable workpiece. The use of the term “about” in conjunction with a numerical value refers to within 20% of the stated numerical value.

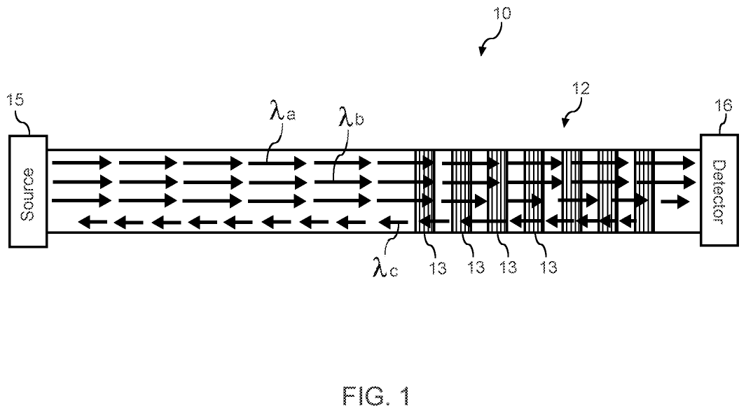

FIG. 1 illustrates a schematic of an optical contact temperature sensor 10 according to example embodiments of the present disclosure. The optical contact temperature sensor 10 can detect thermomechanical properties in a variety of ways. For instance, the sensor 10 can be a fiber Bragg Grating (FGB) sensor that can provide measurements at one or more different locations along the length of the optical fiber 12. For instance, the sensor 10 includes multiple Bragg gratings 13 disposed along the length of the optical fiber 12. The Bragg gratings 13 can be spaced apart from each other in equal distances along the length of the optical fiber 12. In other embodiments, the Bragg gratings 13 can be randomly spaced in a variety of different distances from each other along the length of the optical fiber 12.

The optical fiber 12 can include a single fiber or can include a bundle of multiple fibers. In certain implementations, the optical fiber 12 can be a single-mode optical fiber, which is an optical fiber configured to carry a single ray of light. In some embodiments, the optical fiber 12 can include multiple layers. For instance, the optical fiber 12 can have an inner core and an outer part. The inner core can be formed from a different material as compared to the outer part of the fiber. For instance, the inner core can be formed from a material that has a higher refractive index as compared to the material used to form the outer part. For instance, the inner core can be formed from a doped glass material, such as SiO₂ that has been doped with germanium. The difference in refraction indexes between the inner core and the outer part causes light to propagate only inside the inner core.

Each Bragg grating 13 has a region with a refractive index that differs from that of the optical fiber 12. Accordingly, each Bragg grating 13 will reflect light of a particular band width at the interface between the Bragg grating 13 and the optical fiber 12. For instance, light emitted by a source 15 having wavelengths of λa and λb are not reflected, and are, instead guided by the optical fiber 12 to a signal detector 16. However, a portion of light of wavelength λc is reflected at the interface between each Bragg grating 13 and the optical fiber 12 back to the source 15, while a portion of the light continues onto the signal detector 16. The bandwidth of the reflected light and the resulting reflected energy function is dependent on the wavelength λ of the FGB sensor. The wavelength λ is dependent on various thermomechanical properties experienced by the optical fiber 12, such as temperature. Various known calculations can then be used in order to detect a temperature measurement based on wavelength λ signals reflected. Such methods are known to those of skill in the art.

In embodiments, one or more wavelengths of light can be guided through the optical fiber 12 and the sensor 10 may interact with each wavelength different. For instance, a spectrum of light can be is directed through the optical fiber 12. The reflection spectrum can then be analyzed to measure multiple sensor 10 signals simultaneously. The reflection spectrum can be analyzed, for example, using an interferometer to separate the spectrum according to the wavelengths of its component light rays.

The optical temperature sensors 10 as disclosed herein can be disposed on or positioned on one or more components of a semiconductor fabrication apparatus. Example embodiments of a semiconductor fabrication apparatus suitable for performing the treatment processes of the present disclosure will now be discussed. The terms “semiconductor fabrication apparatus” and “processing apparatus” may be used interchangeably herein.

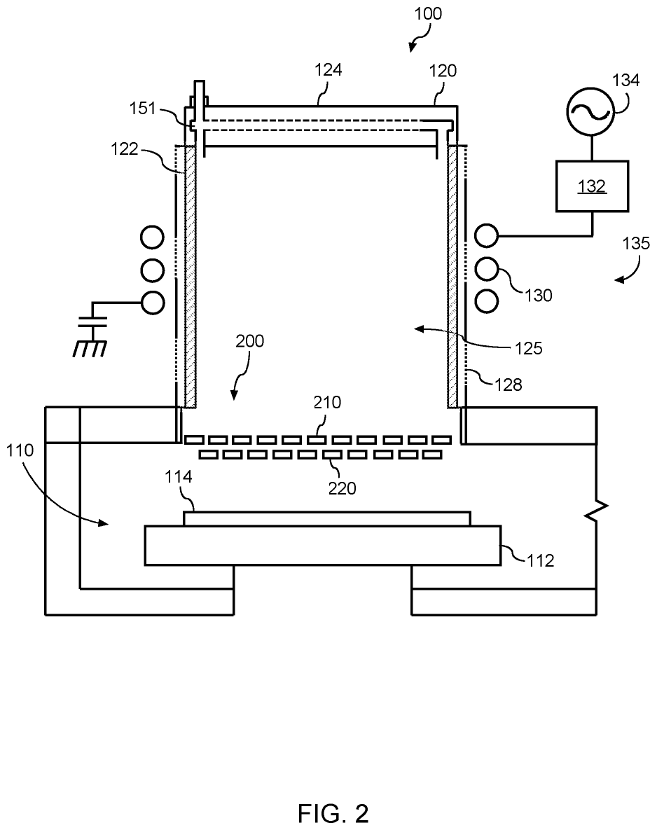

FIG. 2 depicts an example plasma processing apparatus 100 that can be used to perform treatment processes according to example embodiments of the present disclosure. As illustrated, the plasma processing apparatus 100 includes a processing chamber 110 and a plasma chamber 120 that is separated from the processing chamber 110. The processing chamber 110 includes a substrate holder or pedestal 112 operable to hold a workpiece 114 to be processed, such as a semiconductor wafer. In this example illustration, a plasma is generated in the plasma chamber 120 (i.e., plasma generation region) by an inductively coupled plasma source 135 and desired species are channeled from the plasma chamber 120 to the surface of workpiece 114 through a separation grid assembly 200.

Aspects of the present disclosure are discussed with reference to an inductively coupled plasma source for purposes of illustration and discussion. Those of ordinary skill in the art, using the disclosures provided herein, will understand that any plasma source (e.g., inductively coupled plasma source, capacitively coupled plasma source, etc.) can be used without deviating from the scope of the present disclosure.

The plasma chamber 120 includes a dielectric sidewall 122 and a ceiling 124. The dielectric sidewall 122, the ceiling 124, and the separation grid 200 define a plasma chamber interior 125. The dielectric sidewall 122, the ceiling 124, the separation grid 200, and/or the pedestal can be formed from a dielectric material, such as quartz, ceramic, and/or alumina. The inductively coupled plasma source 135 can include an induction coil 130 disposed adjacent the dielectric sidewall 122 about the plasma chamber 120. The induction coil 130 is coupled to an RF power generator 134 through a suitable matching network 132. Process gases (e.g., reactant and/or carrier gases) can be provided to the chamber interior from a gas supply 150 and an annular gas distribution channel 151 or other suitable gas introduction mechanism. When the induction coil 130 is energized with RF power from the RF power generator 134, a plasma can be generated in the plasma chamber 120. In a particular embodiment, the plasma processing apparatus 100 can include an optional grounded Faraday shield 128 to reduce capacitive coupling of the induction coil 130 to the plasma.

One or more controllers (not shown) can be used to control gas flow at various locations on the plasma processing apparatus 100. For instance, one or more controllers can be used to control the gas delivery system 150, which provides gas to the plasma chamber 120. One or more controllers can also be configured to control gas flow for additional gas ports disposed between grid plates of the separation grid 200, embodiments of which will be further discussed hereinbelow.

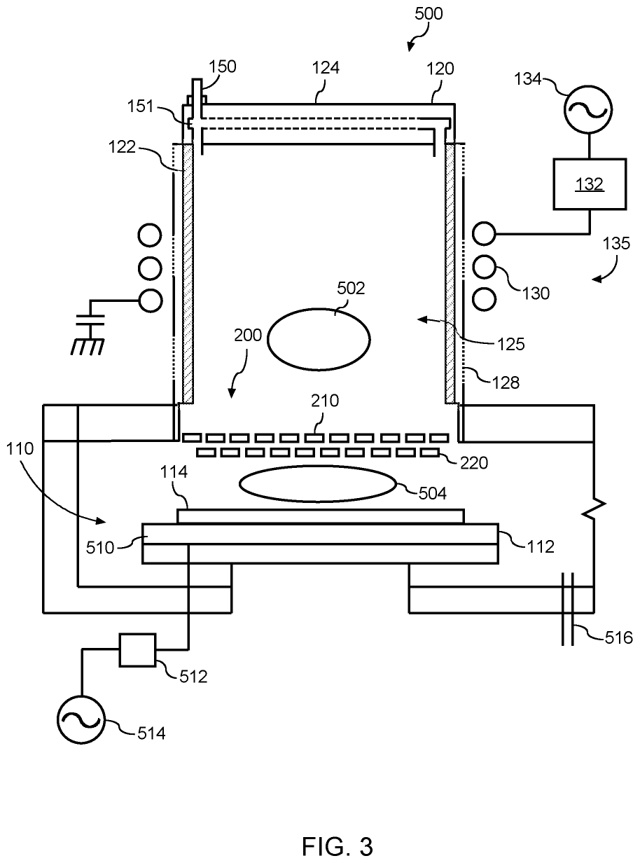

FIG. 3 depicts an example plasma processing apparatus 500 that can be used to implement processes according to example embodiments of the present disclosure. The plasma processing apparatus 500 is similar to the plasma processing apparatus 100 of FIG. 2.

More particularly, plasma processing apparatus 500 includes a processing chamber 110 and a plasma chamber 120 that is separated from the processing chamber 110. Processing chamber 110 includes a substrate holder or pedestal 112 operable to hold a workpiece 114 to be processed, such as a semiconductor wafer. In this example illustration, a plasma is generated in plasma chamber 120 (i.e., plasma generation region) by an inductively coupled plasma source 135 and desired species are channeled from the plasma chamber 120 to the surface of workpiece 114 through a separation grid assembly 200.

The plasma chamber 120 includes a dielectric sidewall 122 and a ceiling 124. The dielectric sidewall 122, ceiling 124, and separation grid 200 define a plasma chamber interior 125. Dielectric sidewall 122 can be formed from a dielectric material, such as quartz and/or alumina. The inductively coupled plasma source 135 can include an induction coil 130 disposed adjacent the dielectric sidewall 122 about the plasma chamber 120. The induction coil 130 is coupled to an RF power generator 134 through a suitable matching network 132. Process gases (e.g., an inert gas) can be provided to the chamber interior from gas supply 150 and annular gas distribution channel 151 or other suitable gas introduction mechanism. When the induction coil 130 is energized with RF power from the RF power generator 134, a plasma can be generated in the plasma chamber 120. In a particular embodiment, the plasma processing apparatus 100 can include an optional grounded Faraday shield 128 to reduce capacitive coupling of the induction coil 130 to the plasma.

As shown in FIG. 3, a separation grid 200 separates the plasma chamber 120 from the processing chamber 110. The separation grid 200 can be used to perform ion filtering from a mixture generated by plasma in the plasma chamber 120 to generate a filtered mixture. The filtered mixture can be exposed to the workpiece 114 in the processing chamber.

In some embodiments, the separation grid 200 can be a multi-plate separation grid. For instance, the separation grid 200 can include a first grid plate 210 and a second grid plate 220 that are spaced apart in parallel relationship to one another. The first grid plate 210 and the second grid plate 220 can be separated by a distance.

The first grid plate 210 can have a first grid pattern having a plurality of holes. The second grid plate 220 can have a second grid pattern having a plurality of holes. The first grid pattern can be the same as or different from the second grid pattern. Charged particles can recombine on the walls in their path through the holes of each grid plate 210, 220 in the separation grid. Neutral species (e.g., radicals) can flow relatively freely through the holes in the first grid plate 210 and the second grid plate 220. The size of the holes and thickness of each grid plate 210 and 220 can affect transparency for both charged and neutral particles.

In some embodiments, the first grid plate 210 can be made of metal (e.g., aluminum) or other electrically conductive material and/or the second grid plate 220 can be made from either an electrically conductive material or dielectric material (e.g., quartz, ceramic, etc.). In some embodiments, the first grid plate 210 and/or the second grid plate 220 can be made of other materials, such as silicon or silicon carbide. In the event a grid plate is made of metal or other electrically conductive material, the grid plate can be grounded.

As discussed above, a hydrogen gas can be injected into species passing through the separation grid 200 to generate one or more hydrogen radicals for exposure to the workpiece 114. The hydrogen radicals can be used to implement a variety of semiconductor fabrication processes.

The example plasma processing apparatus 500 of FIG. 3 is operable to generate a first plasma 502 (e.g., a remote plasma) in the plasma chamber 120 and a second plasma 504 (e.g., a direct plasma) in the processing chamber 110. As used herein, a “remote plasma” refers to a plasma generated remotely from a workpiece, such as in a plasma chamber separated from a workpiece by a separation grid. As used herein, a “direct plasma” refers to a plasma that is directly exposed to a workpiece, such as a plasma generated in a processing chamber having a pedestal operable to support the workpiece.

More particularly, the plasma processing apparatus 500 of FIG. 3 includes a bias source having bias electrode 510 in the pedestal 112. The bias electrode 510 can be coupled to an RF power generator 514 via a suitable matching network 512. When the bias electrode 510 is energized with RF energy, a second plasma 504 can be generated from a mixture in the processing chamber 110 for direct exposure to the workpiece 114. The processing chamber 110 can include a gas exhaust port 516 for evacuating a gas from the processing chamber 110. One or more oxygen radicals used in the pretreatment process and/or the hydrogen radicals used in the hydrogen radical treatment process according to example aspects of the present disclosure can be generated using the first plasma 502 and/or the second plasma 504.

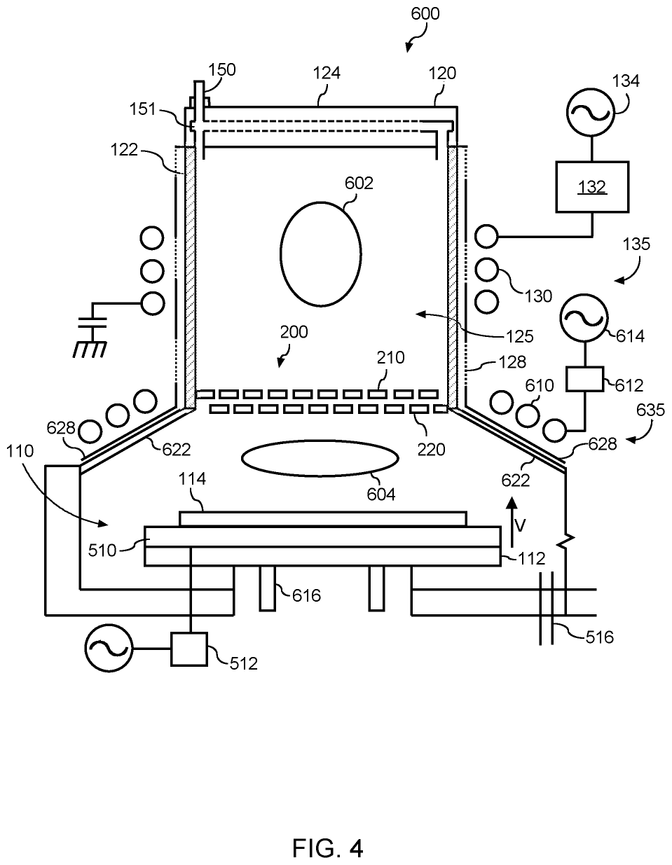

FIG. 4 depicts a processing chamber 600 similar to that of FIG. 2 and FIG. 3. More particularly, plasma processing apparatus 600 includes a processing chamber 110 and a plasma chamber 120 that is separated from the processing chamber 110. Processing chamber 110 includes a substrate holder or pedestal 112 operable to hold a workpiece 114 to be processed, such as a semiconductor wafer. In this example illustration, a plasma is generated in plasma chamber 120 (i.e., plasma generation region) by an inductively coupled plasma source 135 and desired species are channeled from the plasma chamber 120 to the surface of workpiece 114 through a separation grid assembly 200.

The plasma chamber 120 includes a dielectric sidewall 122 and a ceiling 124. The dielectric sidewall 122, ceiling 124, and separation grid 200 define a plasma chamber interior 125. Dielectric sidewall 122 can be formed from a dielectric material, such as quartz and/or alumina. The inductively coupled plasma source 135 can include an induction coil 130 disposed adjacent the dielectric sidewall 122 about the plasma chamber 120. The induction coil 130 is coupled to an RF power generator 134 through a suitable matching network 132. Process gas (e.g., an inert gas) can be provided to the chamber interior from gas supply 150 and annular gas distribution channel 151 or other suitable gas introduction mechanism. When the induction coil 130 is energized with RF power from the RF power generator 134, a plasma can be generated in the plasma chamber 120. In a particular embodiment, the plasma processing apparatus 100 can include an optional grounded Faraday shield 128 to reduce capacitive coupling of the induction coil 130 to the plasma.

As shown in FIG. 4, a separation grid 200 separates the plasma chamber 120 from the processing chamber 110. The separation grid 200 can be used to perform ion filtering from a mixture generated by plasma in the plasma chamber 120 to generate a filtered mixture. The filtered mixture can be exposed to the workpiece 114 in the processing chamber.

In some embodiments, the separation grid 200 can be a multi-plate separation grid. For instance, the separation grid 200 can include a first grid plate 210 and a second grid plate 220 that are spaced apart in parallel relationship to one another. The first grid plate 210 and the second grid plate 220 can be separated by a distance.

The first grid plate 210 can have a first grid pattern having a plurality of holes. The second grid plate 220 can have a second grid pattern having a plurality of holes. The first grid pattern can be the same as or different from the second grid pattern. Charged particles can recombine on the walls in their path through the holes of each grid plate 210, 220 in the separation grid. Neutral species (e.g., radicals) can flow relatively freely through the holes in the first grid plate 210 and the second grid plate 220. The size of the holes and thickness of each grid plate 210 and 220 can affect transparency for both charged and neutral particles.

In some embodiments, the first grid plate 210 can be made of metal (e.g., aluminum) or other electrically conductive material and/or the second grid plate 220 can be made from either an electrically conductive material or dielectric material (e.g., quartz, ceramic, etc.). In some embodiments, the first grid plate 210 and/or the second grid plate 220 can be made of other materials, such as silicon or silicon carbide. In the event a grid plate is made of metal or other electrically conductive material, the grid plate can be grounded.

The example plasma processing apparatus 600 of FIG. 4 is operable to generate a first plasma 602 (e.g., a remote plasma) in the plasma chamber 120 and a second plasma 604 (e.g., a direct plasma) in the processing chamber 110. As shown, the plasma processing apparatus 600 can include an angled dielectric sidewall 622 that extends from the vertical sidewall 122 associated with the remote plasma chamber 120. The angled dielectric sidewall 622 can form a part of the processing chamber 110.

A second inductive plasma source 635 can be located proximate the dielectric sidewall 622. The second inductive plasma source 635 can include an induction coil 610 coupled to an RF generator 614 via a suitable matching network 612. The induction coil 610, when energized with RF energy, can induce a direct plasma 604 from a mixture in the processing chamber 110. A Faraday shield 628 can be disposed between the induction coil 610 and the sidewall 622.

The pedestal 112 can be movable in a vertical direction V. For instance, the pedestal 112 can include a vertical lift 616 that can be configured to adjust a distance between the pedestal 112 and the separation grid assembly 200. As one example, the pedestal 112 can be located in a first vertical position for processing using the remote plasma 602. The pedestal 112 can be in a second vertical position for processing using the direct plasma 604. The first vertical position can be closer to the separation grid assembly 200 relative to the second vertical position.

The plasma processing apparatus 600 of FIG. 3 includes a bias source having bias electrode 510 in the pedestal 112. The bias electrode 510 can be coupled to an RF power generator 514 via a suitable matching network 512. The processing chamber 110 can include a gas exhaust port 516 for evacuating a gas from the processing chamber 110. One or more oxygen radicals used in the pretreatment process and/or one or more hydrogen radicals used in the hydrogen radical treatment processes according to example aspects of the present disclosure can be generated using the first plasma 602 and/or the second plasma 604.

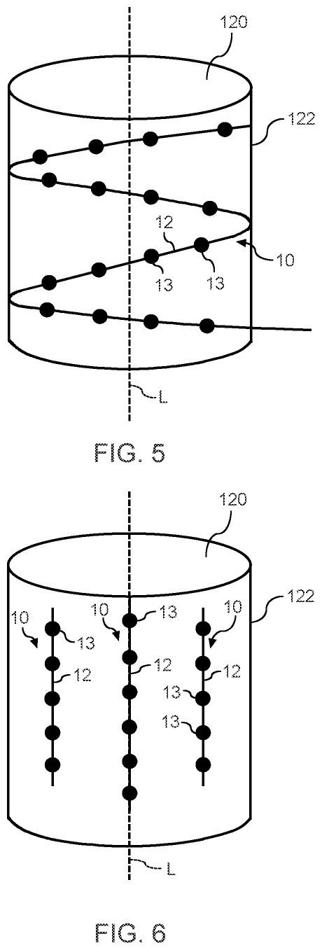

As illustrated in FIGS. 5-10, the optical contact temperature sensor 10 can be disposed on various components of the plasma processing apparatuses of FIGS. 2-4. As shown in FIGS. 5-6, the optical contact temperature sensor 10 is disposed on the dielectric sidewall 122 of the plasma chamber 120. As shown in FIG. 5, the optical contact temperatures sensor 10 including an optical fiber 12 with a plurality of Bragg gratings 13 can be coiled around either the exterior surface or interior surface of the dielectric sidewall 122. The optical contact temperature sensor 10 can be coiled along a longitudinal axis (L) as shown. For instance, the optical contact temperature sensor 10 can coil by completing rotations about axis L from the bottom of the sidewall 122 to the top of the sidewall. In other embodiments, as illustrated in FIG. 6, the optical contact temperature sensor 10 is disposed in a linear pattern along axis L. Additional optical contact temperature sensors 10 can also be disposed in a linear pattern along axis L, as shown in FIG. 6. While multiple optical contact temperature sensors 10 are illustrated, the disclosure is not so limited and can include one optical contact temperature sensors 10 or multiple optical contact temperature sensors 10.

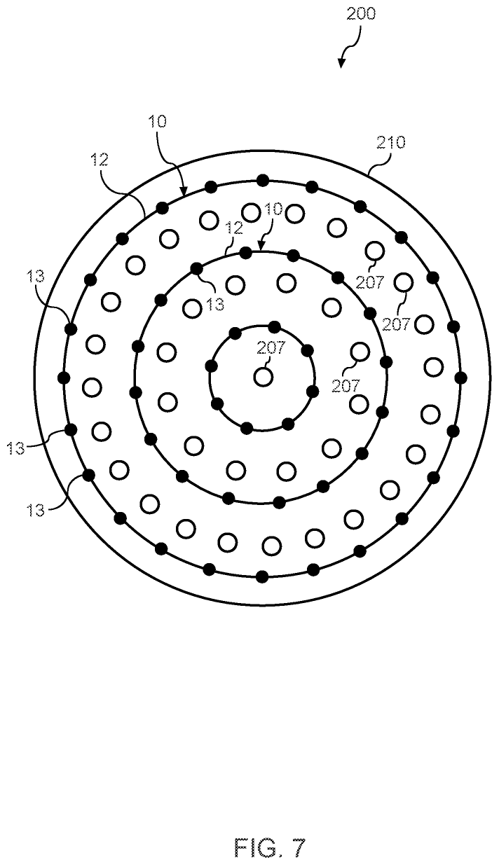

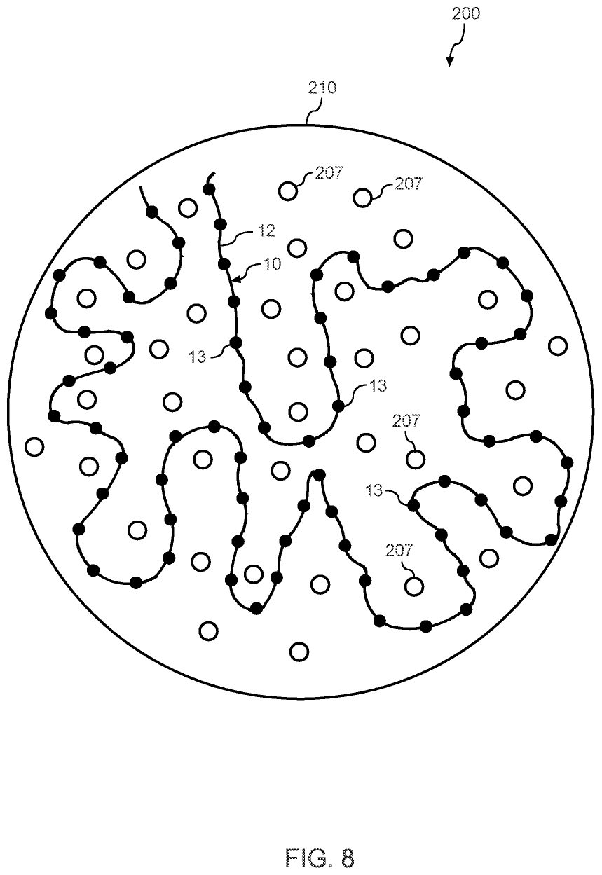

Now referring to FIGS. 7-8, an example grid plate from a separation grid according to the apparatuses of FIGS. 2-4 is illustrated. As shown, the separation grid 200 includes at least one grid plate 210. The grid plate 210 has a variety of holes 207 (or channels) disposed therein for filtering ions from the plasma generated in the plasma chamber. The optical contact temperature sensor 10, including optical fiber and Bragg gratings 13 can be disposed on a surface of the grid plate 210. As shown in FIG. 7, multiple optical contact temperature sensors 10 are disposed in concentric circles on the grid plate 210. The optical contact temperature sensors 10 can be disposed in any manner, but, in some cases, are disposed to enable temperature measurements from a variety of locations across the grid plate 200. The optical contact temperature sensors 10 can be disposed on either side of the grid plate. For instance, in embodiments, one or more optical contact temperature sensors 10 are disposed on the side of the grid plate facing the plasma chamber. In other embodiments, one or more optical contact temperature sensors 10 are disposed on the side of the grid plate facing the processing chamber. As shown in FIG. 8, a single optical contact temperature sensor 10 can be disposed on the grid plate 210 in a random pattern.

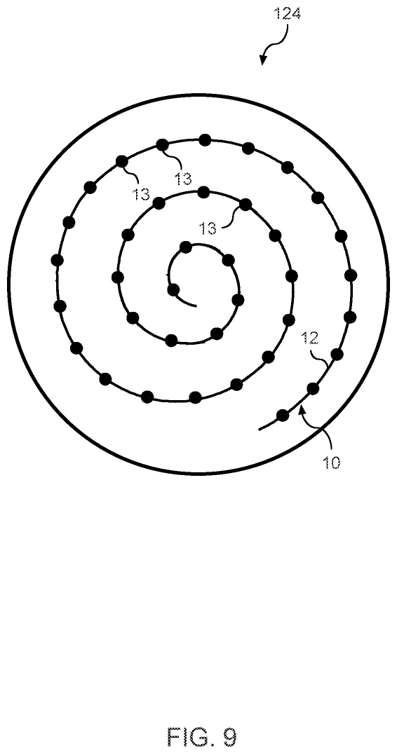

FIG. 9 illustrates an optical contact temperature sensor 10 disposed on the ceiling 124 of the plasma chamber 124. As shown, an optical contact temperature sensor 10 including an optical fiber 12 and a plurality of Bragg gratings 13 is disposed on the ceiling 124 of the plasma chamber 120. While only one optical contact temperature sensor 10 is disclosed, the disclosure is not so limited. In fact, multiple optical contact temperature sensors 10 can be disposed in any pattern on the ceiling 124 of the plasma chamber 120. Further, the optical contact temperature sensor 10 can be disposed on the outer surface of the ceiling 124 or the inner surface of the ceiling.

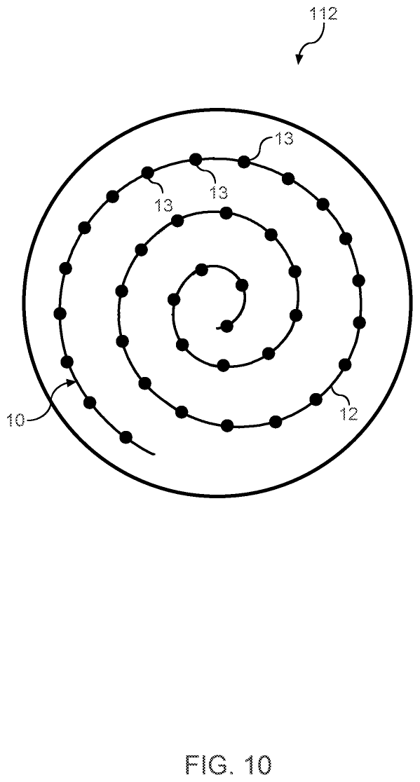

Similar to FIG. 9, FIG. 10 illustrates a pedestal 112 having an optical contact temperature sensor 10 thereon. As shown, the optical contact temperature sensor 10 includes an optical fiber 12 and a plurality of Bragg gratings 13. While only one optical contact temperature sensor 10 is disclosed, the disclosure is not so limited. In fact, multiple optical contact temperature sensors 10 can be disposed in any pattern on the pedestal 112. Further, the optical contact temperature sensor 10 can be disposed on the surface of the pedestal 112 facing the workpiece 114 or on the surface of the pedestal 112 that does not face the workpiece 114.

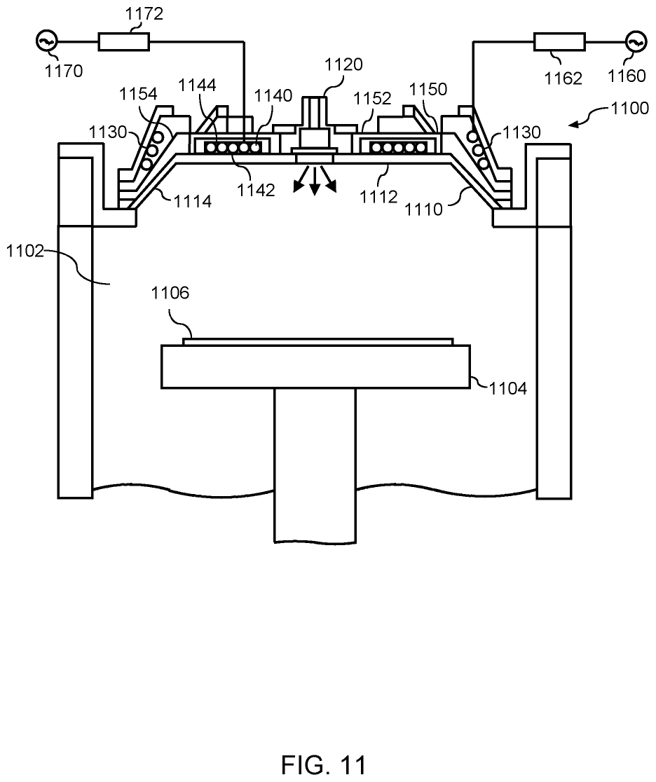

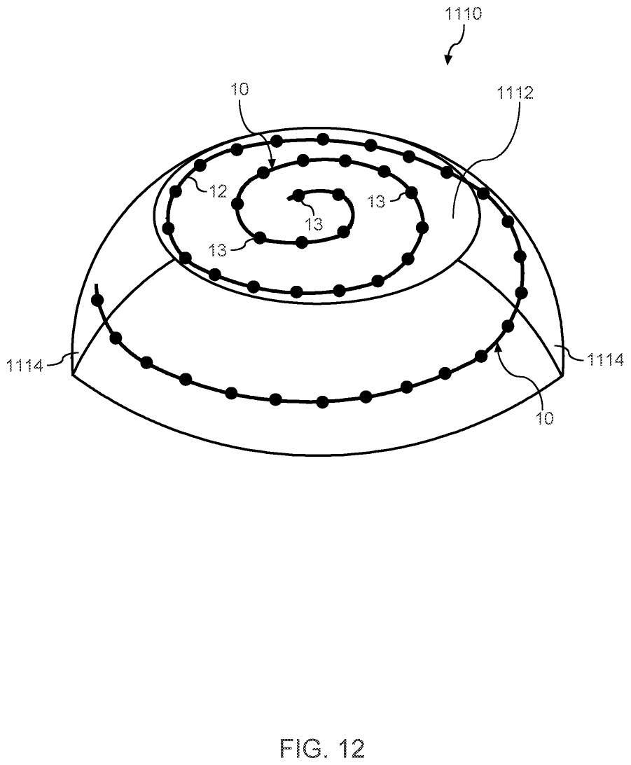

FIG. 11 depicts another plasma processing apparatus 1100 according to an exemplary embodiment of the present disclosure. The plasma processing apparatus 1100 includes a processing chamber defining an interior space 1102. A pedestal or substrate holder 1104 is used to support a substrate 1106, such as a semiconductor wafer, within the interior space 1102. A dielectric window 1110 is located above the substrate holder 1104. The dielectric window 1110 includes a relatively flat central portion 1112 and an angled peripheral portion 1114. The dielectric window 1110 includes a space in the central portion 1112 for a showerhead 1120 to feed process gas into the interior space 1102.

The apparatus 1100 further includes a plurality of inductive elements, such as primary inductive element 1130 and secondary inductive element 1140, for generating an inductive plasma in the interior space 1102. The inductive elements 1130, 1140 can include a coil or antenna element that when supplied with RF power, induces a plasma in the process gas in the interior space 1102 of plasma processing apparatus 1100. For instance, a first RF generator 1160 can be configured to provide electromagnetic energy through a matching network 1162 to the primary inductive element 1130. A second RF generator 1170 can be configured to provide electromagnetic energy through a matching network 1172 to the secondary inductive element 1140.

While the present disclosure makes reference to a primary inductive and a secondary inductive, those of ordinary skill in the art, should appreciate that the terms primary and secondary are used for convenience purposes only. The secondary coil can be operated independent of the primary coil, and vice versa.

According to aspects of the present disclosure, the apparatus 1100 can include a metal shield portion 1152 disposed around the secondary inductive element 1140. As discussed in more detail below, metal shield portion 1152 separates the primary inductive element 1130 and the secondary inductive element 1140 to reduce cross-talk between the inductive elements 1130, 1140. Apparatus 1100 can further include a Faraday shield 1154 disposed between the primary inductive element 1130 and the dielectric window 1130. Faraday shield 1154 can be a slotted metal shield that reduces capacitive coupling between the primary inductive element 1154 and the process chamber 1102. As illustrated, Faraday shield 1154 can fit over the angled portion of the dielectric shield 1110.

In a particular embodiment, metal shield 1152 and Faraday shield 1154 can form a unitary body 1150 for ease of manufacturing and other purposes. The multi-turn coil of the primary inductive element 1130 can be located adjacent the Faraday shield portion 1154 of the unitary body metal shield/Faraday shield 1150. The secondary inductive element 1140 can be located proximate the metal shield portion 1152 of metal shield/Faraday shield unitary body 1150, such as between the metal shield portion 1152 and the dielectric window 1110.

The arrangement of the primary inductive element 1130 and the secondary inductive element 1140 on opposite sides of the metal shield 1152 allows the primary inductive element 1130 and secondary inductive element 1140 to have distinct structural configurations and to perform different functions. For instance, the primary inductive element 1130 can include a multi-turn coil located adjacent a peripheral portion of the process chamber. The primary inductive element 1130 can be used for basic plasma generation and reliable start during the inherently transient ignition stage. The primary inductive element 1130 can be coupled to a powerful RF generator and expensive auto-tuning matching network and can be operated at an increased RF frequency, such as at about 13.56 MHZ.

The secondary inductive element 1140 can be used for corrective and supportive functions and for improving the stability of the plasma during steady state operation. Since the secondary inductive element 1140 can be used primarily for corrective and supportive functions and improving stability of the plasma during steady state operation, the secondary inductive element 1140 does not have to be coupled to as powerful an RF generator as the first inductive element 1130 and can be designed differently and cost effectively to overcome the difficulties associated with previous designs. The secondary inductive element 1140 can also be operated at a lower frequency, such as at about 2 MHZ, allowing the secondary inductive element 1140 to be very compact and to fit in a limited space on top of the dielectric window.

Due to the different frequencies that can be applied to the primary inductive element 1130 and the secondary inductive element 1140, there is reduced interference between the inductive elements 1130, 1140. More particularly, the only interaction in the plasma between the inductive elements 1130, 1140 is through plasma density. Accordingly, there is no need for phase synchronization between the RF generator 1160 coupled to the primary inductive element 1130 and the RF generator 1170 coupled to the secondary inductive element 1140. Power control is independent between the inductive elements. Additionally, since the inductive elements 1130, 1140 are operating at distinctly different frequencies, it is practical to use frequency tuning of the RF generators 1160, 1170 for matching the power delivery into the plasma, greatly simplifying the design and cost of any additional matching networks.

As shown in FIG. 12, an optical contact temperature sensor 10 is disposed on the dielectric window 1110. The optical contact temperature sensor 10 includes an optical fiber and a plurality of Bragg gratings 13. As shown, a first optical contact sensor 10 is disposed on the flat central portion 1112 and a second optical contact temperature sensor 10 is disposed on the angled peripheral portion 1114 of the dielectric window 1110. In embodiments, however, the optical contact temperature sensors 1110 can be disposed only on the flat central portion 1112 or the angled peripheral portion 1112. In certain embodiments, the optical contact temperature sensors 10 are disposed on the outer surface of the dielectric window. In other embodiments, however, the optical contact temperature sensor 10 can be disposed on the inner surface of the dielectric window 1110, which corresponds to the surface facing the processing chamber 1102.

In each of the embodiments depicted and illustrated herein, the optical contact temperature sensor(s) 10 can be used to determine the temperature of multiple components of a plasma processing apparatus in real time. Further, the optical contact temperature sensors 10 can be utilized to determine the temperature of various portions of the component in real time.

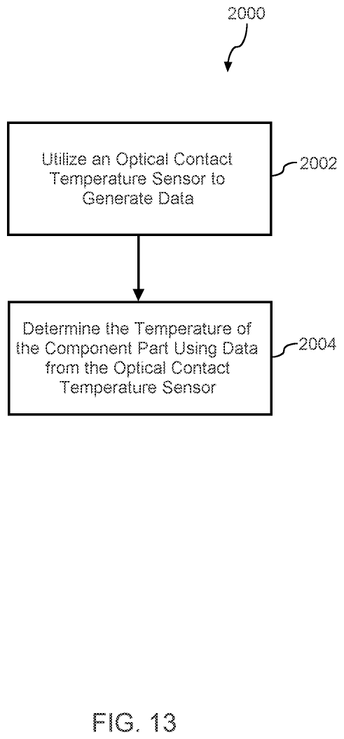

FIG. 13 depicts a flow diagram for a temperature measurement process (2000) for measuring a temperature of a component of a semiconductor fabrication apparatus. The temperature measurement process (2000) can be implemented on the apparatuses as shown in FIG. 2-4 or 11. However, as will be discussed in detail below, the temperature measurement process (2000) according to example aspects of the present disclosure can be implemented using other approaches without deviating from the scope of the present disclosure. FIG. 13 depicts steps performed in a particular order for purposes of illustration and discussion. Those of ordinary skill in the art, using the disclosures provided herein, will understand that various steps of any of the methods described herein can be omitted, expanded, performed simultaneously, rearranged, and/or modified in various ways without deviating from the scope of the present disclosure. In addition, various additional steps (not illustrated) can be performed without deviating from the scope of the present disclosure.

At (2002), the temperature measurement process (2000) includes utilizing an optical contact temperature measurement sensor to generate data regarding the temperature of the component part. For instance, as shown above, the optical contact temperature sensor is disposed on at least one of the component parts of the semiconductor fabrication apparatuses. The optical contact temperature sensor includes an optical fiber having one or more Bragg gratings thereon. Each Bragg grating can reflect light with different phase shifts, which causes interference to occur canceling most of the reflected light. However, the reflections with equal phase shifts accumulate to a strong reflection peak. The bandwidth of reflection and the resulting energy function is dependent on the bandwidth of the FBG sensor. This wavelength is dependent on various thermomechanical properties experienced by the fiber of the optical temperature sensor. Thus, the optical contact temperature sensor can provide data (e.g., reflected wavelength data or phase shift data) that can be utilized to determine temperature.

In some embodiments, one or more wavelengths of light may be guided through the optical fiber and the FGB sensor can interact with each wavelength of light differently. In some embodiments, an optical signal that includes a spectrum of light is guided through the optical contact temperature sensor, and the reflection spectrum is analyzed to measure multiple FBG signals simultaneously.

At (2004), the temperature measurement process (2000) includes determining the temperature of the component part based, at least in part, on the data obtained from the optical temperature sensor. For instance, as described with respect to (2002), the reflection spectrum from the optical temperature sensor 10 can be analyzed, for example, using an interferometer to separate the spectrum according to the wavelengths of its component light rays. Thus, the various thermomechanical properties of the fiber (e.g., temperature) can be calculated according to known methods. Such methods and calculations are known and are further described by U.S. Patent Publication No. 2016/0024912, which is herein incorporated by reference.

Further, data from the optical contact temperature sensor can be transmitted to one or more processors for processing and determining the corresponding temperature. For instance, the optical contact temperature sensor data can be transferred to a computing device capable of executing one or more programs thereon for processing the data from the one or more optical contact temperature sensors for determining the temperature(s) of the component part. The computing device can include a processor, controller, and/or memory all configured to execute machine readable instructions for processing the data from the optical contact temperature sensor.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A semiconductor fabrication apparatus for processing one or more workpieces, the semiconductor fabrication apparatus comprising:
one or more components exposed to radio frequency energy; and
one or more optical contact temperature sensors disposed on the one or more components.

2. The semiconductor fabrication apparatus of claim 1, wherein the one or more optical contact temperature sensors comprises a fiber Bragg gratings (FBG) sensor.

3. The semiconductor fabrication apparatus of claim 2, wherein the FBG sensor comprises a plurality of Bragg gratings disposed at different positions along an optical fiber.

4. The semiconductor fabrication apparatus of claim 3, wherein each Bragg grating has a first refractive index that is different from a second refractive index of the optical fiber.

5. The semiconductor fabrication apparatus of claim 1, wherein the one or more components comprise a sidewall of a plasma chamber.

6. The semiconductor fabrication apparatus of claim 1, wherein the one or more components comprise a separation grid.

7. The semiconductor fabrication apparatus of claim 1, wherein the one or more components comprise a pedestal.

8. The semiconductor fabrication apparatus of claim 1, wherein the one or more components comprise a quartz material.

9. The semiconductor fabrication apparatus of claim 1, wherein the one or more components comprise a ceramic material.

10. The semiconductor fabrication apparatus of claim 1, wherein the optical temperature sensor is coiled along a longitudinal axis of the one or more components.

11. The semiconductor fabrication apparatus of claim 1, wherein the optical temperature sensor is disposed in a linear pattern along a length of the one or more components.

12. The semiconductor fabrication apparatus of claim 1, wherein the optical temperature sensor is capable of sensing temperatures in a range from about 0° C. up to about 1000° C.

13. An apparatus for processing a workpiece, the apparatus comprising:
a plasma chamber having a sidewall;
an inductively coupled plasma source configured to generate a plasma in the plasma chamber;
a processing chamber separated from the plasma chamber via a separation grid;
a pedestal disposed in the processing chamber, the pedestal configured to support a workpiece during processing; and
an optical contact temperature sensor disposed on at least one of (i) the sidewall of the plasma chamber (ii) the separation grid or (iii) the pedestal.

14. The apparatus of claim 13, wherein the optical contact temperature sensor comprises a fiber Bragg gratings (FBG) sensor.

15. The apparatus of claim 14, wherein the FBG sensor comprises a plurality of Bragg gratings disposed at different positions along an optical fiber.

16. The apparatus of claim 13, wherein the optical contact temperature sensor is coiled along a longitudinal axis of the sidewall of the plasma chamber.

17. The apparatus of claim 13, wherein the optical contact temperature sensor is disposed in a linear pattern along a longitudinal axis of the sidewall of the plasma chamber.

18. The apparatus of claim 13, wherein the sidewall of the plasma chamber comprises a quartz material or a ceramic material.

19. A method for measuring temperature of a component of a semiconductor fabrication apparatus, the method comprising:
utilizing an optical contact temperature sensor to generate data regarding temperature of a component part, the optical contact temperature sensor disposed on the component part; and
determining the temperature of the component part based, at least in part, on the data obtained from the optical contact temperature sensor.

20. The method of claim 19, wherein the optical contact temperature sensor comprises a FGB sensor.
